(19) United States
(12) Patent Application Publication
(10) Pub. No.: US 2011/0157835 A1
(43) Pub. Date: Jun. 30, 2011

(54) Heat sink assembly

(75) Inventors: Tien-Chun Feng, Keelung City (TW); Chao-Jung Chen, Taipei City (TW); Wen-Liang Huang, Taoyuan Shien (TW)

(73) Assignee: Quanta Computer Inc., Taoyuan Shien (TW)

(21) Appl. No.: 12/659,430

(22) Filed: Mar. 9, 2010

(30) Foreign Application Priority Data
Dec. 31, 2009 (TW) 098225022

(51) Int. Cl. H05K 7/20; F28F 7/00

(52) U.S. Cl. 361/718; 361/720; 165/185

(57) ABSTRACT

A heat sink assembly is provided. The heat sink assembly comprises a heat sink and a clip. The heat sink comprises a heat-dissipating baseboard and a plurality of heat-dissipating plates. The heat-dissipating baseboard is adapted to a heating element. The heat-dissipating plates are formed perpendicularly on the heat-dissipating baseboard and parallel to each other. The clip comprises a central portion, two winding portions and two locking portions. The central portion is placed in a containing space between two of the heat-dissipating plates and is riveted on the heat-dissipating baseboard. The length of the central portion is substantially the same as the length of the heating element. The winding portions are connected to the two ends of the central portion respectively and aren't contacted to the heat-dissipating baseboard. The locking portions are formed substantially perpendicularly on the two winding portions and each has a hook stretching out in opposite directions.

### RELATED APPLICATIONS

This application claims priority to Taiwan Application Serial Number 98225022, filed Dec. 31, 2009, which is herein incorporated by reference.

### BACKGROUND

1. Technical Field

The present disclosure relates to heat-dissipating device. More particularly, the present disclosure relates to heat sink assembly.

2. Description of Related Art

Computer technology is one of the most important inventions in human culture. Many chips in a computer system together deal with user data requests. However, these chips consume power. A great deal of heat is generated during the operation of the chips. If the power-dissipating mechanism is not good enough, the chips may be damaged because of overheating.

The heat-dissipating device is often placed on the top of the chip to provide a heat-dissipating mechanism. Nevertheless, computer chips are becoming smaller and smaller with advances in modern technology, whereas heat-dissipating devices need a larger area to provide a better heat-dissipating mechanism. The heat-dissipating device with a large area is not easy to keep steady on the top of a chip that has a much smaller area. If the heat-dissipating device is not able to completely touch the surface of the chip due to a bad fastening mechanism, the efficiency of the heat-dissipating mechanism decreases. If the contact area between the heat-dissipating device and the chip is too small, the chip may be damaged due to the poor heat-dissipating efficiency.

Accordingly, what is needed is a heat sink assembly to keep steady on the chip to provide a better heat-dissipating mechanism. The present disclosure addresses such a need.

### SUMMARY

An aspect of the present disclosure is to provide a heat sink assembly comprising: a heat sink and a clip. The heat sink comprises a heat-dissipating baseboard and a plurality of heat-dissipating plates. The heat-dissipating baseboard is adapted to a heating element. The heat-dissipating plates are formed perpendicularly on the heat-dissipating baseboard and parallel to each other. The clip comprises a central portion, two winding portions and two locking portions. The central portion is placed in a containing space between two of the heat-dissipating plates and is riveted on the heat-dissipating baseboard. The length of the central portion is substantially the same as the length of the heating element. The two winding portions are connected to the two ends of the central portion respectively and don't touch the heat-dissipating baseboard. The two locking portions are formed substantially perpendicularly on the two winding portions, wherein each of the locking portions has a hook stretching out in opposite directions.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

to FIG. 1 is an exploded view of a heat sink assembly of an embodiment of the present disclosure;

FIG. 2A is a 3-D view of the heat sink and the clip placed on a circuit board, wherein the heat sink and the clip are connected to each other;

FIG. 2B is the side perspective view of FIG. 2A along the direction labeled as A; and

FIG. 3 is a 3-D view of the heat sink and the clip placed and locked on the circuit board.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

Please refer to FIG. 1. FIG. 1 is an exploded view of a heat sink assembly 1 of an embodiment of the present disclosure. The heat sink assembly 1 comprises a heat sink 10 and a clip 12.

The heat sink 10 comprises a heat-dissipating baseboard 100 and a plurality of heat-dissipating plates 102. The heat-dissipating plates 102 are formed perpendicularly on the heat-dissipating baseboard 100 and parallel to each other. A containing space 104 is formed between each pair of the heat-dissipating plates 102.

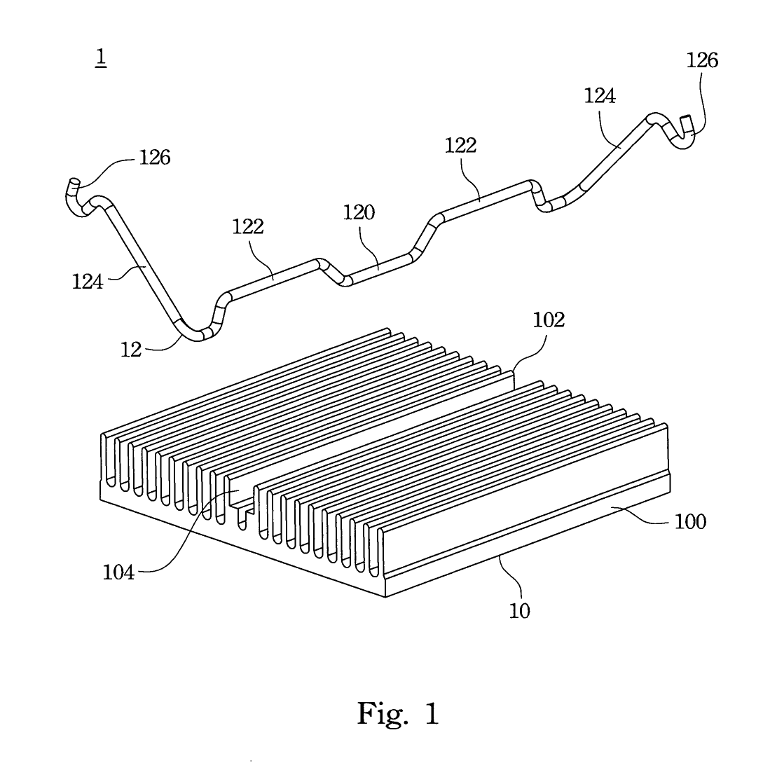

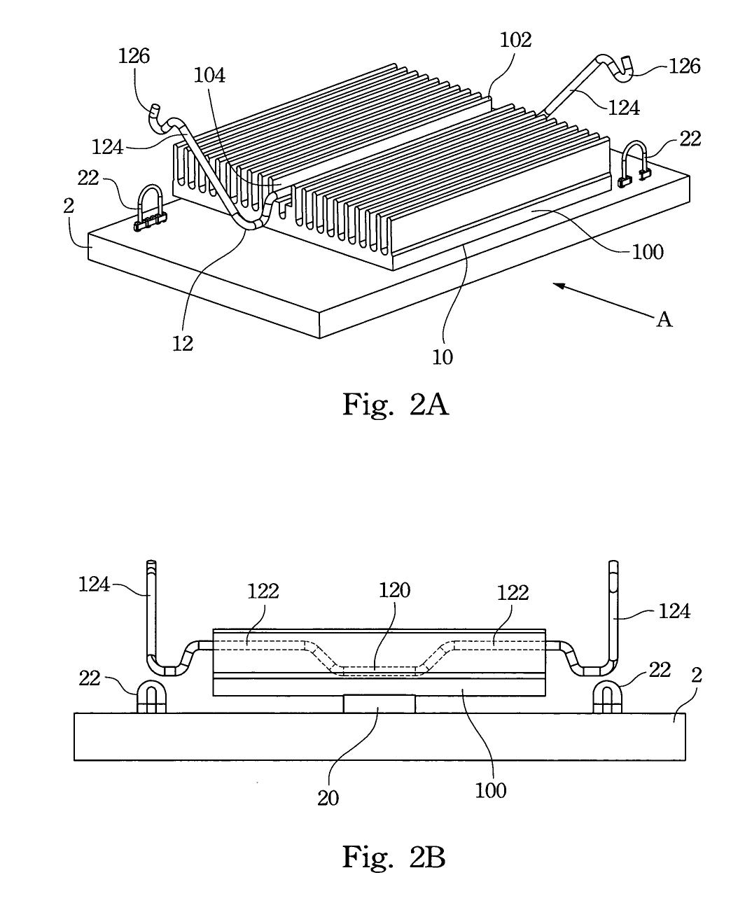

Please refer to FIG. 2A and FIG. 2B at the same time. FIG. 2A is a 3-D view of the heat sink 10 and the clip 12 placed on a circuit board 2, wherein the heat sink 10 and the clip 12 are connected to each other. FIG. 2B is the side perspective view of FIG. 2A along the direction labeled as A. The circuit board 2 comprises a heating element 20 (depicted in FIG. 2B). In an embodiment, the heating element 20 is a chip that is able to generate a great deal of heat during the operation. The heat-dissipating baseboard 100 of the heat sink 10 is adapted to the heating element 20 to transmit the heat from the heating element 20 to the heat-dissipating plates 102. Consequently, the heat is dissipated through the heat-dissipating plates 102. In an embodiment, the heat sink 10 is made of metal to provide an efficient heat-dissipating mechanism. However, the contact area between the heat sink 10 and the heating element 20 should be as large as possible to provide a better heat-dissipating mechanism. In other words, the heat sink 10 and the heating element 20 have to be connected to each other tightly. If the heat sink 10 with larger area is not able to be securely placed on the heating element 20 with a smaller area, the efficiency of the heat-dissipating mechanism decreases. If the contact area between the heat sink 10 and the heating element 20 is too small, the heating element 20 may be damaged due to the poor heat-dissipating efficiency.

The clip 12 comprises a central portion 120, two winding portions 122 and two locking portions 124. The central portion 120 is placed in the containing space 104 between two of the heat-dissipating plates 102. In an embodiment, the central portion 120 is placed in the containing space 104 between the two most central heat-dissipating plates 102, as depicted in FIG. 1. When the clip 12 is connected to the heat sink 10 as shown in FIG. 2A and FIG. 2B, the central part 120 is substantially riveted on the heat-dissipating baseboard 100 to provide a better fastening mechanism. The length of the central portion 120 is substantially the same as the length of the heating element 20.

As is known to those skilled in the art and as is used in this application, “substantially the same as” means that the actual length of the central portion 120 may differ slightly from the length of the heating element 20 within a tolerable range and still be considered the same. The length of the central portion 120 may not be absolutely the same as the length of the heating element 20. In other words, the length of the central portion 120 may be slightly larger or smaller than the length of the heating element 20 without affecting the function of the central portion 120. In an embodiment, the central portion 120 is riveted on the edges of the heat-dissipating baseboard 100.

The two winding portions 122 are connected to the two ends of the central portion 120 respectively and don't touch the heat-dissipating baseboard 100 even when the clip 12 and the heat sink 10 are connected to each other. The two winding portions 122 further stretch out the containing space 104 from the central portion 102. Because of the angle of the winding portions 122, the clip 12 is not able to rotate within the containing space 104 due to the obstruction of the two winding portions 122.

The two locking portions 124 are formed substantially perpendicularly on the ends of the two winding portions 122 stretching out of the containing space 104 respectively, wherein each of the locking portions 124 has a hook 126 stretching out in opposite directions.

As is known to those skilled in the art and as is used in this application, “substantially perpendicularly” means that the actual angle between the locking portions 124 and the winding portions 122 may differ slightly from 90 degrees. In other words, the angle may be slightly larger or smaller than 90 degrees without affecting the function of the locking portions 124 and the winding portions 122.

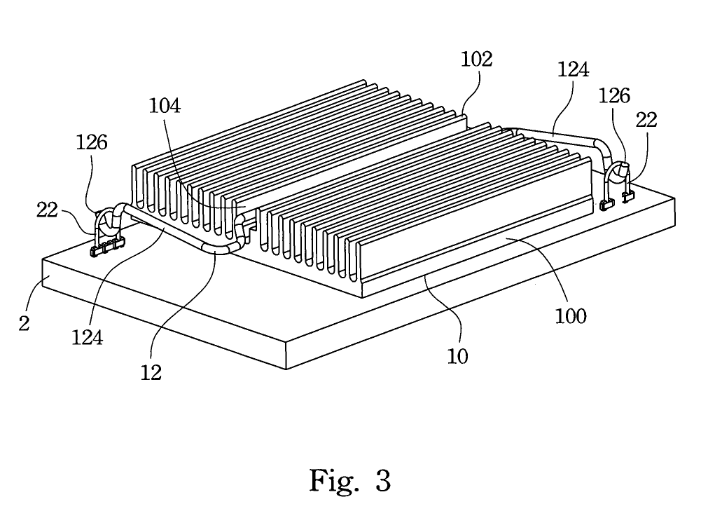

Two locking rings 22 are formed on the circuit board 2. Please refer to FIG. 3. FIG. 3 is a 3-D view of the heat sink 10 and the clip 12 placed and locked on the circuit board 2. In an embodiment, the clip 12 is made of elastic metal. Therefore, the two locking portions 124 can stretch out such that the hooks 126 are adapted to the two locking rings 22. When the hooks 126 are adapted to the locking rings 22, the central portion 120 applies a force on the heat-dissipating baseboard 100 to press the heating element 20 underneath. As a result, the heat sink 10 and the heating element 20 can be connected to each other tightly.

Through the locking mechanism of the clip 12 and the circuit board 2, the heat sink 10 is able to be connected tightly with the heating element 20 to have the largest contact area. The length of the central portion 120 is substantially the same as the heating element 20, therefore the lever of force is smaller to avoid the forces from the locking portions 124 and the winding portion 122 make the heat sink 10 tilt. The central portion 120 is riveted to the heat sink 10 to avoid sliding, and the winding portions 122 prevent the central portion 120 from rotating. Consequently, the heat sink assembly 1 can provide a better heat-dissipating efficiency due to the above features.

It will be apparent to those skilled in the art that various modifications and variations can be made to the structure of the present disclosure without departing from the scope or spirit of the invention. In view of the foregoing, it is intended that the present disclosure cover modifications and variations of this invention provided they fall within the scope of the following claims.

What is claimed is:

1. A heat sink assembly comprising:
a heat sink comprising:
a heat-dissipating baseboard adapted to a heating element; and
a plurality of heat-dissipating plates formed perpendicularly on the heat-dissipating baseboard and being parallel to each other; and
a clip comprising:
a central portion placed in a containing space between two of the heat-dissipating plates and riveted on the heat-dissipating baseboard, wherein the length of the central portion is substantially the same as the length of the heating element;
two winding portions connected to the two ends of the central portion respectively and not contacted to the heat-dissipating baseboard, wherein the two winding portions further stretches out of the containing space from the central portion; and
two locking portions formed substantially perpendicularly on the two winding portions, wherein each of the locking portions has a hook stretching out in opposite directions.

2. The heat sink assembly of claim 1, wherein the heating element is a chip.

3. The heat sink assembly of claim 1, wherein the heating element is formed on a circuit board having two locking rings formed thereon, whereas each of the two locking portions is adapted to one the two locking rings.

4. The heat sink assembly of claim 3, when the two locking portions are adapted to the two locking rings, the central portion applies a force on the heat-dissipating baseboard to press the heating element.

5. The heat sink assembly of claim 1, wherein the clip is not able to rotate within the containing space due to the obstruction of the two winding portions.

6. The heat sink assembly of claim 1, wherein the central portion is placed in the containing space between the two most central heat-dissipating plates.

7. The heat sink assembly of claim 1, wherein the clip is elastic metal.

8. The heat sink assembly of claim 1, wherein the central portion is riveted on an edge of the heat-dissipating baseboard.
